(19) United States
(12) Patent Application Publication
(10) Pub. No.: US 2025/0052438 A1
(43) Pub. Date: Feb. 13, 2025

(54) AIR PURIFYING SYSTEM AND METHOD ADAPTED FOR MOVABLE ENCLOSED SPACE

(71) Applicants: Vicki-Fen CHOU, Taoyuan (TW); Philip TRINH, Taoyuan (TW); Christine TRINH, Taoyuan (TW)

(72) Inventor: Song CHOU, Taoyuan (TW)

(21) Appl. No.: 18/792,767

(22) Filed: Aug. 2, 2024

Related U.S. Application Data
(60) Provisional application No. 63/532,104, filed on Aug. 11, 2023.

(51) Int. Cl. F24F 8/192; F24F 11/70

(52) U.S. Cl. CPC F24F 8/192; F24F 11/70

(57) ABSTRACT

Provided are an air purifying system and method adapted for a movable enclosed space. The air purifying system includes a charged gas generating source, a blowing system, a circulation system, and one or more electrical neutralization devices. The electrical neutralization devices are disposed in the movable enclosed space to neutralize charged gas in the movable enclosed space. The charged gas generating source which generates the charged gas with negative ions in high concentration and the electrical neutralization devices disposed in the movable enclosed space not only enable persons in the movable enclosed space to access high-quality air but also preclude any adverse impact of negative ions in high concentration on important electrical equipment.

### CROSS-REFERENCE TO RELATED APPLICATIONS

This application claims priority to U.S. Provisional Patent Application No. 63/532,104 filed in U.S. on Aug. 11, 2023 the entire contents of which are hereby incorporated by reference.

### BACKGROUND OF THE INVENTION

### Field of the Invention

The present disclosure relates to air purifying equipment technology, and more particularly to an air purifying system and method adapted for a movable enclosed space in a transport carrier or a wearable device.

### Description of the Prior Art

The higher the concentration of negative oxygen ions in air is, the more marked is the positive effect on the body and mind of every human being. Furthermore, the World Health Organization (WHO) defines negative oxygen ion concentration in clean air as “greater than 1500 ions/cm³”.

Chinese utility model patent CN2600753Y discloses an air purifier that essentially has a casing, negative oxygen ion generating mechanism, gripping element, power control mechanism, etc. The negative oxygen ion generating mechanism is disposed in the casing and has a negative-pressure component, rotating element, negative oxygen ion generating board, electrically-conductive clamp, etc., so as to generate negative oxygen ions. Negative oxygen ions are contained in air generated by the negative oxygen ion generating mechanism while the air purifier is operating. The negative oxygen ions absorb dust and bacteria in air to render the air clean and fresh. The air purifier is compact, easy to transport and install, and suitable for use in small space, as well as exhibits ease of use and practicability. In particular, the air purifier has the gripping element clamped and disposed at a cool air outlet through which cool air is released to the surroundings. The cool air carries the negative oxygen ions generated from the air purifier, allowing the negative oxygen ions to spread throughout the surroundings.

Chinese utility model patent CN2648327Y discloses a ceiling fan sterilizing and air purifying device that has therein a motor connected to a fan. The axle of the fan is connected to a controller. The controller controllably causes the motor to rotate and a cold cathode fluorescent lamp to turn on and turn off. The cold cathode fluorescent lamp generates negative oxygen ions to oxidize organic compounds, produce inorganic compounds by reduction, improve the effect of deodorization, eliminate suspended bacteria from air, and enhance indoor air quality.

The scenes at which existing air purifying device or negative oxygen ion generating devices operate are mostly environments which are relatively not enclosed, i.e., indoor environments, and convection still occurs between each relatively non-enclosed environment and an outdoor, ambient environment. People nowadays often stay in relatively enclosed moving carriers, such as airplanes, and some special groups stay inside environments, such as ship cabins or submarines, or are confined to relatively enclosed wearable equipment, for a long period of time. Regarding the aforesaid enclosed moving carriers, conventional requirements for air quality are restricted to bacteria, virus, odor and the like in air but have never given rise to any exploration of how to enable air in confined, moving carriers to attain the air quality in natural environments. Great enhancement of air quality requires the presence of high-concentration negative oxygen ions in air. Although charged air makes a difference in physical sensing, considerations must be given to the effect of charged gas on electrical equipment in whatever environments. Therefore, there is still room for improvement in the technology of providing high-quality air to a movable enclosed space.

### SUMMARY OF THE INVENTION

It is an objective of the disclosure to provide an air purifying system and method adapted for a movable enclosed space to not only enable persons in the movable enclosed space to access high-quality air but also preclude any adverse impact of negative ions in high concentration on important electrical equipment.

In one aspect, the air purifying system adapted for a movable enclosed space comprises: a charged gas generating source for generating charged gas; a blowing system for blowing the charged gas away from the charged gas generating source; a circulation system for enabling circulation of the charged gas in the movable enclosed space; and one or more electrical neutralization devices disposed in the movable enclosed space to achieve electrical neutralization of the charged gas.

In a specific embodiment, an air purifying device has a first space and the charged gas generating source and the blowing system which are disposed in the first space, the charged gas generating source charging gas in the first space, and the blowing system blowing the charged gas out of the first space to the circulation system.

In a specific embodiment, the circulation system has a second space in communication with the first space to receive the charged gas from the blowing system.

In a specific embodiment, the circulation system has an outlet channel through which the charged gas enters the movable enclosed space.

In a specific embodiment, the circulation system has an inlet channel through which the charged gas in the movable enclosed space enters the second space.

In a specific embodiment, the outlet channel and the inlet channel are in communication with each other.

In a specific embodiment, the electrical neutralization devices are disposed in the inlet channel to achieve electrical neutralization of the charged gas having entered the circulation system, preventing the charged gas from damaging the air purifying device.

In a specific embodiment, the electrical neutralization devices are connected to a ground end but do not share the ground end with other electronic devices.

In a specific embodiment, the movable enclosed space is an enclosed space of a transport carrier or an enclosed space of a wearable device.

In a specific embodiment, the charged gas generating source and the blowing system are integrally formed.

In a specific embodiment, the charged gas generating source comprises a casing. The casing has therein a negative ion generating circuit board. An insulating material is filled between the outer surface of the negative ion generating circuit board and the inner wall of the casing. The insulating material which fills the casing effectively limits the movement of electrostatic charges and thus effectively reduces the accumulation of electrostatic charges. Since the hazards associated with electrostatic charges are effectively reduced, the charged gas generating source achieves high ion emissions to enhance air purifying effect and purification efficiency.

The disclosure further provides a method of controlling an air purifying system, the method is applicable to N air purifying systems, wherein N is an integer greater than or equal to 2. The control method comprises the steps of: obtaining the optimal operating frequency range of each of the air purifying systems in operation; determining, when negative ion concentration of charged gas in the movable enclosed space is less than a predetermined level, whether the operating frequencies of all the air purifying systems in an operating state reach an upper limit of the optimal operating frequency range, wherein the number of the air purifying systems in an operating state is denoted by k, where k<N; controllably causing the (k+1)^{th} air purifying system to open when the operating frequencies of all the air purifying systems in an operating state reach an upper limit of the optimal operating frequency range; performing down-conversion control on the k air purifying systems and performing up-conversion control on the (k+1)^{th} air purifying system when the operating frequency of the (k+1)^{th} air purifying system does not reach a lower limit of the optimal operating frequency range and the negative ion concentration of the charged gas reaches the predetermined level to controllably cause the operating frequencies of the k+1 air purifying systems to fall within the optimal operating frequency range when the negative ion concentration of the charged gas reaches the predetermined level. The method involves performing systematic adjustment to the entire system to cause, to the greatest extent possible, each of the air purifying systems to operate within the optimal operating frequency range, enhance the performance of the entire system, effectively prevent a portion of the systems from operating at a high frequency band and the other portion of the systems from operating at a low frequency band to the detriment of the overall performance of the system.

In another aspect, another objective of the disclosure is to provide an air purifying method adapted for a movable enclosed space, comprising the steps of: providing a circulation system having at least one outlet channel and at least one inlet channel, wherein both the outlet channel and the inlet channel are in communication with the movable enclosed space; providing a charged gas generating source in the movable enclosed space; blowing, by a blowing system, charged gas generated from the charged gas generating source into the outlet channel of the circulation system; monitoring the charged gas in the movable enclosed space and controlling the charged gas generating source and/or the circulation system according to whether concentration of negative ions in the movable enclosed space falls within a predetermined range; and providing an electrical neutralization device in the movable enclosed space to insulate electrical equipment in the movable enclosed space.

The technical solution provided by the disclosure has features and advantages over the prior art as follows:

The charged gas generating source which generates the charged gas with negative ions in high concentration and the electrical neutralization devices disposed in the movable enclosed space not only enable persons in the movable enclosed space to access high-quality air but also preclude any adverse impact of negative ions in high concentration on important electrical equipment.

### BRIEF DESCRIPTION OF THE DRAWINGS

The present disclosure is depicted by accompanying drawings and reference numerals therein, illustrated by non-restrictive, non-exhaustive embodiments, and described below. The accompanying drawings are not drawn to scale but are aimed at disclosing the structural features and principles of the disclosure.

FIG. 1 is a schematic view of an air purifying system adapted for a movable enclosed space according to the present disclosure.

FIG. 2 is a schematic view of a process flow of an air purifying method adapted for a movable enclosed space according to the present disclosure.

### DETAILED DESCRIPTION OF THE EMBODIMENTS

The present disclosure is depicted by accompanying drawings, fully described below, and illustrated by exemplary, specific embodiments to explain specific examples. However, the subject matter of the present disclosure can be specifically implemented in many different forms, and thus the construction of the subject matter included or claimed is not limited by any exemplary, specific embodiments of the present disclosure; the exemplary, specific embodiments merely serve illustrative purposes. Similarly, the description of the present disclosure herein is aimed at providing reasonably broad scope of protection to the subject matter included or claimed. Furthermore, the accompanying drawings of the present disclosure are neither drawn to scale nor aimed at corresponding in dimensions to real components and elements shown in the accompanying drawings.

Like components and elements are mostly denoted by like reference numerals in the illustrative accompanying drawings to ensure consistency and ease of comprehension. However, features of the present disclosure may vary from embodiment to embodiment in other aspects, and thus interpretation of the present disclosure must not be strictly restricted to the features shown in the accompanying drawings. Ordinal numbers, such as “first” and “second,” used herein and in the accompanying drawings are intended to distinguish identical or similar components or elements and do not necessarily imply what order the components or elements are in in terms of space or time.

The present disclosure provides an air purifying system adapted for a movable enclosed space, such as an enclosed space of a moving carrier, i.e., an enclosed space of a transport carrier (airplane, ship, submarine, vehicle, or high-speed rail) or wearable device (helmet, diving gear or astronaut gear). The moving carrier or wearable device comes with a circulation system and an air purifying system, providing at least one outlet channel and at least one inlet channel which are in communication with the movable enclosed space. According to the present disclosure, the air purifying system further comprises an air purifying device. The air purifying device generates charged gas. The charged gas carries negative ions in high concentration.

The “enclosed space” of the present disclosure is not completely confined but is an internal space that undergoes no or just slight convection relative to an external space for a long period of time, for example, airplane cabin space, ship cabin space, submarine internal space, and special-purpose helmet. The oxygen content in the movable enclosed spaces decreases with time, but the carbon dioxide content in the movable enclosed spaces increases with time, undermining the performance of persons working in the movable enclosed spaces. The “negative ions” mentioned in the present disclosure is not restrictive the types of the negative ions, which can exist in the form of hydroxide ion (OH) attached to water, i.e., (H₂O+OH⁻), in the form of oxygen ion attached to water, i.e., (O²⁻+H₂O), and/or in the form of carbon tetroxide attached to water, i.e., (CO₄⁴⁻+H₂O).

Air carrying negative ions in high concentration are introduced into the movable enclosed spaces to increase the number of negative ions per cubic centimeter (for example, negative ion concentration) in the movable enclosed spaces to a predetermined range. Preferably, the predetermined range is greater than 1500 ions/cm³.

Air carrying negative ions are obtained from the charged gas generating source. In general, the charged gas generating source has a high voltage generator. The high voltage generator is in contact with air at an electrical discharge end to generate negative ions. The electrical discharge end is disposed near the outlet channel.

The blowing system (for example, a fan) keeps air flowing at the electrical discharge end to enable oxygen to pass the electrical discharge end continuously and thus generate charged gas carrying negative ions continuously.

The electrical discharge end of the charged gas generating source is disposed near the outlet channel of the circulation system. The negative ions in high concentration generated through the contact between the electrical discharge end and air are blown out of the outlet channel by the blowing system, and in consequence there is circulation of air with negative ions in high concentration inside the enclosed space of the moving carrier.

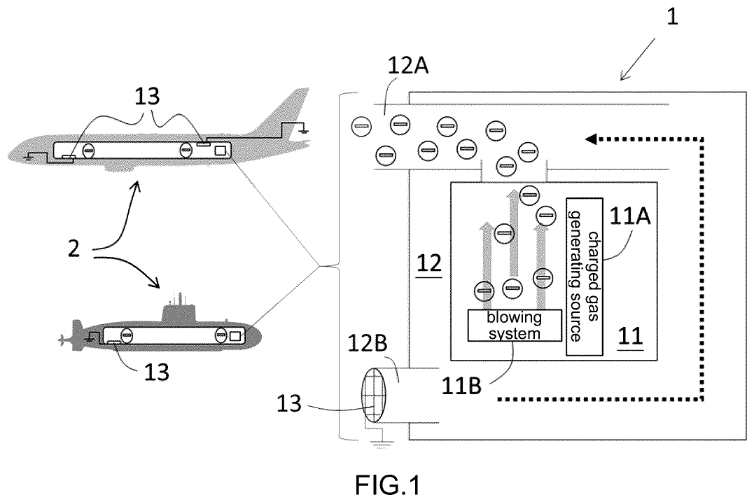

FIG. 1 is a schematic view of an air purifying system 1 of the present disclosure. According to the present disclosure, the air purifying system 1 is disposed in a transport carrier 2, such as an airplane cabin or a submarine cabin.

The air purifying system 1 comprises an air purifying device 11 and a circulation system 12 which are connected in communication with each other.

The air purifying device 11 has a charged gas generating source 11A and a blowing system 11B. The charged gas generating source 11A is controlled by a controller to generate a high voltage field for ionizing air and thus obtaining charged gas carrying negative ions. The charged gas generating source 11A ionizes air in a first space. The first space is the space inside the air purifying device 11 and in the vicinity of the charged gas generating source 11A, but the present disclosure is not limited thereto. The blowing system 11B is disposed near the charged gas generating source 11A and configured to create convection whereby charged gas ionized by the charged gas generating source 11A is driven away to enter the circulation system 12. The blowing system 11B comprises one or more electric fans controlled by the controller to determine wind speed or gas flow direction.

Optionally, the charged gas generating source 11A and the blowing system 11B are integrally formed. For example, the blowing system 11B comprises one or more electric fans, and the charged gas generating source 11A is disposed beside blades of the electric fans. The electric fans of the blowing system 11B are close enough to the charged gas generating source 11A to achieve structural simplicity. The electric fans operate to enhance the speedy diffusion of negative ions generated from the charged gas generating source 11A, increasing indoor negative ion effectively and quickly and improving indoor environment.

The charged gas generating source 11A comprises a casing. The casing has therein a negative ion generating circuit board. An insulating material is filled between the outer surface of the negative ion generating circuit board and the inner wall of the casing. The insulating material which fills the casing effectively limits the movement of electrostatic charges and thus effectively reduces the accumulation of electrostatic charges. Since the hazards associated with electrostatic charges are effectively reduced, the charged gas generating source 11A achieves high ion emissions to enhance air purifying effect and purification efficiency.

The circulation system 12 defines a second space therein. The second space is in communication with the first space of the air purifying device 11. The circulation system 12 has an outlet channel 12A and an inlet channel 12B which are in communication with the second space and the enclosed space of the transport carrier 2. The second space of the circulation system 12 is in communication with the first space through the outlet channel 12A, so that the charged gas blown out by the blowing system 11B can enter the outlet channel 12A of the circulation system 12 before entering the enclosed space. The inlet channel 12B receives gas from the enclosed space and returns the gas to the circulation system 12, the ion concentration of the gas thus recycled may be diluted or neutralized and thus is overly low. The recycled charged gas proceeds to the outlet channel 12A via a specific path in the second space and mixes with the charged gas which have been blown to the outlet channel 12A from the first space.

The air purifying system 1 of the present disclosure further comprises one or more electrical neutralization devices 13. The electrical neutralization devices 13 reduce or neutralize the electrical polarity of the charged gas, so as to prevent negative ions in high concentration from coming into contact with other electrical equipment and thus causing electrostatic damage or electromagnetic interference. The electrical neutralization devices 13 are mainly made of metal and formed to take various shapes, such as net-shaped, sheet-shaped or block-shaped. In the embodiment illustrated by FIG. 1, the electrical neutralization devices 13 are net-shaped and are disposed on the inlet channel 12B of the circulation system 12. Alternatively, the electrical neutralization devices 13 are disposed at appropriate positions in the enclosed space of the transport carrier 2, for example, provided in net-shaped or sheet-shaped and disposed on the wall of the cabin of an airplane or on the wall of a ship cabin. The electrical neutralization devices 13 are connected to a ground end such that the electrical neutralization devices 13 themselves have zero electric potential or low electric potential. In an embodiment, the circulation system 12 is disposed along the wall of the enclosed space, whereas the multiple outlet channels 12A and multiple inlet channels 12B are distributed in the enclosed space, with multiple electrical neutralization devices 13 disposed in such a way to insulate electrical equipment from the enclosed space. Thus, when the charged gas flows from the enclosed space to the electrical equipment, the amount of charges carried by the gas must be reduced by the electrical neutralization devices 13 so as to avoid affecting the operation of the electrical equipment.

The enclosed space has therein ion concentration detectors for monitoring the negative ion concentration of the charged gas in the enclosed space and sending the detection result to the controller. The controller regulates the operation of the charged gas generating source 11A, blowing system 11B and circulation system 12 according to the real-time negative ion concentration level or the average negative ion concentration level.

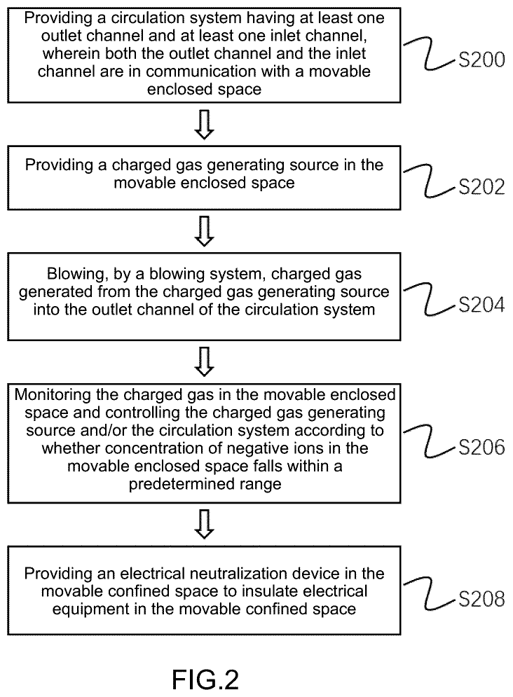

FIG. 2 is a schematic view of a process flow of an air purifying method of the present disclosure, briefly describing step S200 through step S208.

Step S200: Providing a circulation system 12 having at least one outlet channel 12A and at least one inlet channel 12B, wherein both the outlet channel 12A and the inlet channel 12B are in communication with the movable enclosed space. In an embodiment, the circulation system 12 reaches multiple points of the movable enclosed space to ensure effective circulation throughout the movable enclosed space.

Step S202: Providing a charged gas generating source 11A in the movable enclosed space, and the charged gas generating source 11A is regulated by a controller to generate charged gas, allowing the concentration of negative ions of the charged gas to range from 1500 ions/cm³ to 5000 ions/cm³, or even higher.

Step S204: Blowing, by a blowing system 11B, charged gas generated from the charged gas generating source 11A into the outlet channel 12A of the circulation system 12. The blowing system 11B and the circulation system 12 are appropriately configured to cause the charged gas flowing to the outlet channel 12A instead of back to the inlet channel 12B.

Step S206: Monitoring the charged gas in the movable enclosed space and controlling the charged gas generating source 11A and/or the circulation system 12 according to whether concentration of negative ions in the movable enclosed space falls within a predetermined range, for example, 1500 ions/cm³ to 5000 ions/cm³. Multiple ion concentration detectors are disposed in the movable enclosed space to read a specific negative ion concentration level and send the specific negative ion concentration level to the controller to regulate the operation of the charged gas generating source 11A and the circulation system 12.

Step S208: Providing the electrical neutralization devices 13 in the movable enclosed space to insulate electrical equipment in the movable enclosed space, so as to protect the electrical equipment against electrostatic damage or signal interference otherwise caused by the charged gas. Placing the electrical neutralization devices 13 on a metallic surface that has zero electric potential or low electric potential.

In conclusion, the disclosure provides an air purifying system and method adapted for a movable enclosed space, generating charged gas carrying negative ions in high concentration with a charged gas generating source, and providing electrical neutralization devices in the movable enclosed space, to not only enable persons in the movable enclosed space to access high-quality air but also preclude any adverse impact of negative ions in high concentration on important electrical equipment.

The disclosure further provides another method of controlling an air purifying system, the method is applicable to N air purifying systems, wherein N is an integer greater than or equal to 2. The control method comprises the steps of: obtaining the optimal (compressor) operating frequency range of each of the air purifying systems in operation; determining, when negative ion concentration of charged gas in the movable enclosed space is less than a predetermined level, whether the operating frequencies of all the air purifying systems in an operating state reach an upper limit of the optimal operating frequency range, wherein the number of the air purifying systems in an operating state is denoted by k, where k<N; controllably causing the (k+1)^{th} air purifying system to open when the operating frequencies of all the air purifying systems in an operating state reach an upper limit of the optimal operating frequency range; performing down-conversion control on the k air purifying systems and performing up-conversion control on the (k+1)^{th} air purifying system when the operating frequency of the (k+1)^{th} air purifying system does not reach a lower limit of the optimal operating frequency range and the negative ion concentration of the charged gas reaches the predetermined level to controllably cause the operating frequencies of the k+1 air purifying systems to fall within the optimal operating frequency range when the negative ion concentration of the charged gas reaches the predetermined level. The method involves performing systematic adjustment to the entire system to cause, to the greatest extent possible, each of the air purifying systems to operate within the optimal operating frequency range, enhance the performance of the entire system, effectively prevent a portion of the systems from operating at a high frequency band and the other portion of the systems from operating at a low frequency band to the detriment of the overall performance of the system.

Although the present disclosure is disclosed above by preferred embodiments, the preferred embodiments are illustrative rather than restrictive of the present disclosure. Changes made by persons skilled in the art to the preferred embodiments without departing from the claims of the present disclosure must be deemed falling within the scope of the claims of the present disclosure. Accordingly, the legal protection for the present disclosure should be defined by the appended claims.

What is claimed is:

1. An air purifying system adapted for a movable enclosed space, the air purifying system comprising:
a charged gas generating source for generating charged gas;
a blowing system for blowing the charged gas away from the charged gas generating source;
a circulation system for enabling circulation of the charged gas in the enclosed space; and
one or more electrical neutralization devices disposed in the enclosed space to achieve electrical neutralization of the charged gas.

2. The air purifying system adapted for a movable enclosed space of claim 1, further comprising an air purifying device having a first space and the charged gas generating source and the blowing system which are disposed in the first space, the charged gas generating source charging gas in the first space, and the blowing system blowing the charged gas out of the first space to the circulation system.

3. The air purifying system adapted for a movable enclosed space according to claim 2, wherein the circulation system has a second space in communication with the first space to receive the charged gas from the blowing system.

4. The air purifying system adapted for a movable enclosed space according to claim 3, wherein the circulation system has an outlet channel through which the charged gas enters the enclosed space.

5. The air purifying system adapted for a movable enclosed space according to claim 4, wherein the circulation system has an inlet channel through which the charged gas in the enclosed space enters the second space.

6. The air purifying system adapted for a movable enclosed space according to claim 5, wherein the outlet channel and the inlet channel are in communication with each other.

7. The air purifying system adapted for a movable enclosed space according to claim 6, wherein the electrical neutralization devices are disposed in the inlet channel to achieve electrical neutralization of the charged gas having entered the circulation system.

8. The air purifying system adapted for a movable enclosed space according to claim 1, wherein the electrical neutralization devices are connected to a ground end but do not share the ground end with other electronic devices.

9. The air purifying system adapted for a movable enclosed space according to claim 1, wherein the enclosed space is an enclosed space of a transport carrier or an enclosed space of a wearable device.

10. An air purifying method adapted for a movable enclosed space, comprising the steps of:
providing a circulation system having at least one outlet channel and at least one inlet channel, wherein both the outlet channel and the inlet channel are in communication with the enclosed space;
providing a charged gas generating source in the enclosed space;
blowing, by a blowing system, charged gas generated from the charged gas generating source into the outlet channel of the circulation system;
monitoring the charged gas in the enclosed space and controlling the charged gas generating source and/or the circulation system according to whether concentration of negative ions in the enclosed space falls within a predetermined range; and
providing an electrical neutralization device in the enclosed space to insulate electrical equipment in the enclosed space.
